(19) United States
(12) Patent Application Publication
(10) Pub. No.: US 2011/0017287 A1
(43) Pub. Date: Jan. 27, 2011

(54) SUBSTRATES FOR PHOTOVOLTAICS

(76) Inventors: Nicholas Francis Borrelli, Elmira, NY (US); Douglas Warren Hall, Corning, NY (US); Glenn Eric Kohnke, Corning, NY (US); Alexandre Michel Mayolet, Corning, NY (US)

Correspondence Address: CORNING INCORPORATED, SP-TI-3-1, CORNING, NY, 14831, US

(21) Appl. No.: 12/517,459

(22) PCT Filed: Mar. 24, 2009
(86) PCT No.: PCT/US09/01849

§ 371 Date: Jun. 3, 2009

Related U.S. Application Data
(60) Provisional application No. 61/039,398, filed on Mar. 25, 2008.

(51) Int. Cl. H01L 31/0216

(52) U.S. Cl. 136/256

(57) ABSTRACT

Light scattering substrates, superstrates, and/or layers for photovoltaic cells are described herein. Such structures can be used for volumetric scattering in thin film photovoltaic cells.

This application claims the benefit of priority to U.S. Provisional Patent Application 61/039,398 filed on Mar. 25, 2008.

### BACKGROUND

1. Field of the Disclosure

Embodiments relate generally to photovoltaic cells, and more particularly to light scattering substrates and superstrates for photovoltaic cells.

2. Technical Background

For thin-film silicon photovoltaic solar cells, light advantageously is effectively coupled into the silicon layer and subsequently trapped in the layer to provide sufficient path length for light absorption. A light path length greater than the thickness of the silicon is especially advantageous.

A typical tandem cell incorporating both amorphous and microcrystalline silicon typically has a substrate having a transparent electrode deposited thereon, a top cell of amorphous silicon, a bottom cell of microcrystalline silicon, and a back contact or counter electrode. Light is typically incident from the side of the deposition substrate such that the substrate becomes a superstrate in the cell configuration.

Amorphous silicon absorbs primarily in the visible portion of the spectrum below 700 nanometers (nm) while microcrystalline silicon absorbs similarly to bulk crystalline silicon with a gradual reduction in absorption extending to about 1200 nm. Both types of material can benefit from surfaces having enhanced scattering and/or improved transmission.

The transparent electrode (also known as transparent conductive oxide, TCO) is typically a film of fluorine doped SnO₂ (FTO) or aluminum doped or boron doped ZnO (AZO or BZO, respectively) with a thickness on the order of 1 micron that is textured to scatter light into the amorphous Si and the microcrystalline Si. The primary measure of scattering is called “haze” and is defined as the ratio of light that is scattered greater than 2.5 degrees out of a beam of light going into a cell and the total forward light transmitted through the cell. Due to the wavelength dependence of scattering surfaces, haze is typically not a constant value across the wide solar spectrum between 300 nm and 1200 nm. Also, as mentioned above, the light trapping is more important for long wavelengths than it is for short wavelengths which are absorbed in a single pass through even thin layers of silicon.

In several conventional photovoltaic applications, haze is about 10 percent to 15 percent measured at a wavelength of 550 nm. However, the scattering distribution function is not captured by this single parameter and large angle scattering is more beneficial for enhanced path length in the silicon compared with narrow angle scattering. The literature on different types of scattering functions indicates that improved large angle scattering has a significant impact on cell performance.

The TCO surface can be textured by various techniques. For FTO, for example, the texture can be controlled by the parameters of the chemical vapor deposition (CVD) process used to deposit the films. For AZO or BZO, plasma treatment or wet etching is typically used to create the desired morphology after deposition.

In the past, the haze value was typically reported as a single number. The long wavelength response is particularly important for the microcrystalline silicon. More recently, wavelength dependent haze values have been reported. Since the scattering is directly related to both wavelength and the size of the scatterers, the wavelength response can be modified by changing the size of the features on the textured surface. Large and small feature sizes can be combined in a single texture to provide scattering at both long and short wavelengths. Such a structure also combines the functionality of light trapping with improved transmission. On the other hand, for amorphous Si, shorter wavelengths are advantageous.

Disadvantages with textured TCO technology can include one or more of the following: 1) texture roughness degrades the quality of the deposited silicon and creates electrical shorts such that the overall performance of the solar cell is degraded; 2) texture optimization is limited both by the textures available from the deposition or etching process and the decrease in transmission associated with a thicker TCO layer; and 3) plasma treatment or wet etching to create texture adds cost in the case of ZnO.

Another approach to the light-trapping needs for thin film silicon solar cells is texturing of the substrate beneath the silicon prior to silicon nitride deposition, rather than texture a deposited film. In some conventional thin film silicon solar cells, vias are used instead of a TCO to make contacts at the bottom of the Si that is in contact with the substrate. The texturing in some conventional thin film silicon solar cells consist of SiO₂ particles in a binder matrix deposited on a planar glass substrate. This type of texturing is typically done using a sol-gel type process where the particles are suspended in liquid, the substrate is drawn through the liquid, and subsequently sintered. The beads remain spherical in shape and are held in place by the sintered gel.

Disadvantages with the textured glass substrate approach can include one or more of the following: 1) sol-gel chemistry and associated processing is required to provide binding of glass microspheres to the substrate; 2) the process creates textured surfaces on both sides of the glass substrate; 3) additional costs associated with silica microspheres and sol-gel materials; and 4) problems of film adhesion and/or creation of cracks in the silicon film.

Many additional methods have been explored for creating a textured surface prior to TCO deposition. These methods include sandblasting, polystyrene microsphere deposition and etching, and chemical etching. These methods related to textured surfaces can be limited in terms of the types of surface textures that can be created.

Light trapping is also beneficial for bulk crystalline Si solar cells having a Si thickness less than about 100 microns. At this thickness, there is insufficient thickness to effectively absorb all the solar radiation in a single or double pass (with a reflecting back contact). Therefore, cover glasses with large scale geometric structures have been developed to enhance the light trapping. For example, an EVA (ethyl-vinyl acetate) encapsulant material is located between the cover glass and the silicon. An example of such cover glasses are the Albarino® family of products from Saint-Gobain Glass. A rolling process is typically used to form this large-scale structure.

It would be advantageous to have substrates with light scattering properties which are sufficient for light trapping, particularly at longer wavelengths. Further, it would be advantageous for the substrates to be planar, for example, enabling subsequent film deposition without deleterious electronic effects.

### SUMMARY

Substrates, as described herein, address one or more of the above-mentioned disadvantages of conventional substrates useful for photovoltaic applications.

One embodiment is a photovoltaic device comprising a substrate comprising an inorganic matrix and a region having light scattering properties disposed in the inorganic matrix, a conductive material adjacent to the substrate, and an active photovoltaic medium adjacent to the conductive material.

Another embodiment is a photovoltaic device comprising a substrate, a layer comprising an inorganic matrix and a region having light scattering properties disposed in the inorganic matrix, a conductive material wherein the layer is in physical contact with the substrate and is located between the substrate and the conductive material, and an active photovoltaic medium adjacent to the conductive material.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1 is an illustration of features of a photovoltaic device according to one embodiment.

FIG. 2 is an illustration of features of a photovoltaic device according to one embodiment.

FIG. 3 is an illustration of features of a photovoltaic device according to one embodiment.

FIG. 4a, FIG. 4b, FIG. 4c, and FIG. 4d are illustrations of scattering substrates according to some embodiments.

FIG. 5 is a scanning electron micrograph (SEM) of exemplary particle shapes, distribution, and sizes according to some embodiments.

FIG. 6 is a scanning electron micrograph (SEM) of exemplary particle shapes, distribution, and sizes according to some embodiments.

FIG. 7 is a scanning electron micrograph (SEM) of exemplary particle shapes, distribution, and sizes according to some embodiments.

FIG. 8 is a graph showing transmission into air as a function of particle density for particles having diameters of 500 nm.

FIG. 9 is a graph of integrand (the product of the Si absorptance, the solar spectrum, and the wavelength) versus the wavelength for particles having diameters of 500 nm.

FIG. 10 is a graph of transmittance and reflectance for the optimized particle density of 5e6.

FIG. 11 is a graph of corresponding angular intensity for the optimized particle density of 5e6.

FIG. 12 is a graph of transmittance versus wavelength for substrates, according to one embodiment, using a photosensitive glass.

FIG. 13 is a graph of angular intensity for a Fota-Lite™ substrate, according to one embodiment.

FIG. 14 is a graph of total transmittance versus wavelength for a layer, according to one embodiment.

FIG. 15 is a graph of diffuse transmittance versus wavelength for a layer, according to one embodiment.

FIG. 16 is a graph of angular intensity for a layer, according to one embodiment.

### DETAILED DESCRIPTION

Reference will now be made in detail to various embodiments of the invention, examples of which are illustrated in the accompanying drawings. Wherever possible, the same reference numbers will be used throughout the drawings to refer to the same or like parts.

As used herein, the term “volumetric scattering” can be defined as the effect on paths of light created by inhomogeneities in the refractive index of the materials that the light travels through.

As used herein, the term “surface scattering” can be defined as the effect on paths of light created by interface roughness between layers in a photovoltaic cell.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module.

As used herein, the term “adjacent” can be defined as being in close proximity. Adjacent structures may or may not be in physical contact with each other. Adjacent structures can have other layers and/or structures disposed between them.

As used herein, the term “planar” can be defined as having a substantially topographically flat surface.

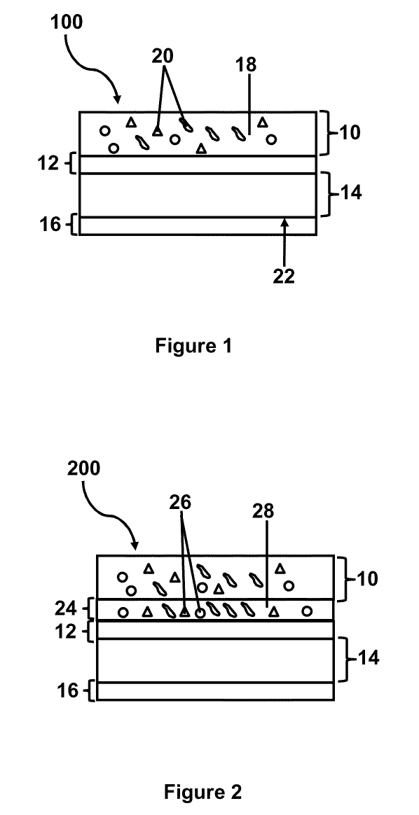

One embodiment, as shown in FIG. 1, is a photovoltaic device 100 comprising a substrate 10 comprising an inorganic matrix 18 and a region 20 having light scattering properties disposed in the inorganic matrix, a conductive material 12 adjacent to the substrate, and an active photovoltaic medium 14 adjacent to the conductive material.

In one embodiment, also shown in FIG. 1, the photovoltaic device 100 further comprises a counter electrode 16 in physical contact with the active photovoltaic medium 14 and located on an opposite surface 22 of the active photovoltaic medium 14 as the conductive material 12.

The active photovoltaic medium, according to one embodiment, is in physical contact with the conductive material. The conductive material, according to one embodiment is a transparent conductive film, for example, a transparent conductive oxide. The transparent conductive film can comprise a textured surface.

The region, according to one embodiment, comprises one or more particles, bodies, spheres, precipitates, crystals, dendrites, phase separated elements, phase separated compounds, air bubbles, air lines, voids or combinations thereof. Alternatively, for example, the region can comprise multiple particles, multiple bodies, multiple spheres, multiple precipitates, multiple crystals, multiple dendrites, multiple phase separated elements, multiple phase separated compounds, multiple air bubbles, multiple air lines, multiple voids, or combinations thereof.

In one embodiment, the matrix comprises a material selected from glass, glass ceramic, and combinations thereof. The region, in one embodiment, comprises a material selected from a glass, glass ceramic, ceramic, a metal oxide, a metals oxide, and combinations thereof.

The photovoltaic device 200, in one embodiment as shown in FIG. 2, further comprises a layer 24 comprising an inorganic matrix 28 and a region 26 having light scattering properties disposed in the inorganic matrix, wherein the layer is in physical contact with the substrate 10 and is located between the substrate 10 and the conductive material 12.

According to some embodiments, the layer is 1 mm or less in thickness, for example, 800 μm or less, for example, 500 μm or less, for example, 250 μm or less, for example, 100 μm or less, for example, 50 μm or less, for example, 25 μm or less, for example, 15 μm or less, for example, 10 μm or less. According to another embodiment, the layer is 1 μm or more in thickness, for example from 1 μm to 10 μm.

The active photovoltaic medium comprises multiple layers, in some embodiments. For example, the multiple layers can comprise one or more p-n junctions, for example in a Si cell. The active photovoltaic medium comprises, in one embodiment, a tandem junction, CdTe, or copper indium gallium (di)selenide (CIGS).

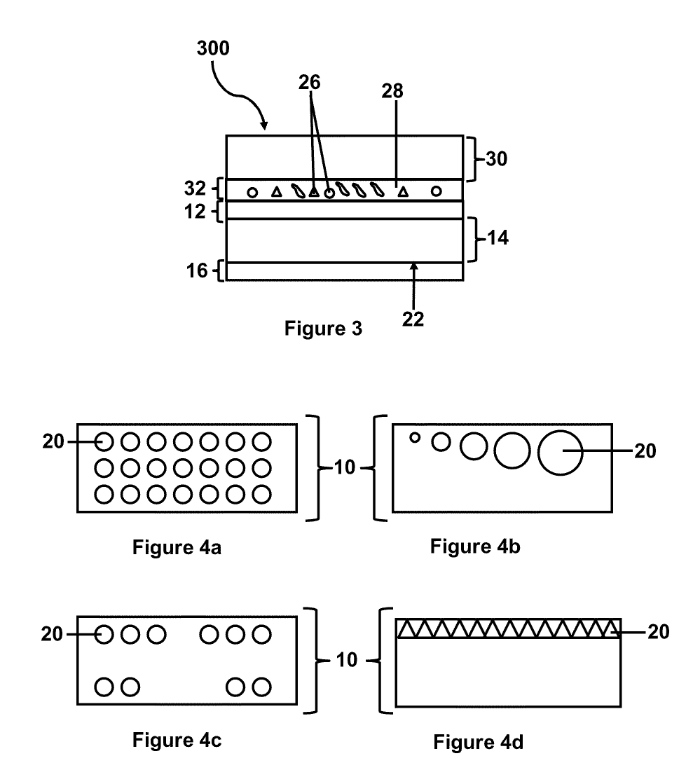

Another embodiment as shown in FIG. 3 is a photovoltaic device 300 comprising a substrate 30, a layer 32 comprising an inorganic matrix 28 and a region 26 having light scattering properties disposed in the inorganic matrix, a conductive material 12 wherein the layer is in physical contact with the substrate 30 and is located between the substrate and the conductive material, and an active photovoltaic medium 14 adjacent to the conductive material.

According to some embodiments, the layer is 1 mm or less in thickness, for example, 800 μm or less, for example, 500 μm or less, for example, 250 μm or less, for example, 100 μm or less, for example, 50 μm or less, for example, 25 μm or less, for example, 15 μm or less, for example, 10 μm or less. According to another embodiment, the layer is 1 μm or more in thickness, for example from 1 μm to 10 μm.

In one embodiment, also shown in FIG. 3, the photovoltaic device 300 further comprises a counter electrode 16 in physical contact with the active photovoltaic medium 14 and located on an opposite surface 22 of the active photovoltaic medium 14 as the conductive material 12.

In the embodiment shown in FIG. 3, the substrate may or may not comprise volumetric scattering properties. According to one embodiment, the substrate is transparent. The substrate, according to one embodiment comprises a material selected from glass, glass ceramic, and combinations thereof.

As discussed above, conventional silicon photovoltaic cells utilize structured surfaces as a means to redirect light within the silicon layer and enhance the photon path length. An alternative method is to use volumetric scattering within a planar substrate. Such materials have been used in light diffusion applications. Common examples include opal glass and glass ceramics.

The substrate, in one embodiment, comprises a plurality of regions dispersed throughout the volume of the inorganic matrix. In another embodiment, the substrate comprises a plurality of regions dispersed throughout a portion of the volume of the inorganic matrix. There may be further advantage for patterning of the scattering region within the substrate while maintaining a planar surface for subsequent deposition, for example, of a TCO.

In some embodiments, the substrate comprises regions disposed in a gradient from top to bottom throughout the thickness, from left to right throughout the thickness, from top to bottom throughout a portion of the thickness, from left to right throughout a portion of the thickness, or combinations thereof. Regions disposed in a pattern or patterns could also comprise the described gradients within the pattern or patterns. Exemplary embodiments of substrates 10 with regions are shown in FIG. 4a, FIG. 4b, FIG. 4c, and FIG. 4d. Matrix materials, region structures, region materials, and region placement can be the same as previously described, according to some embodiments.

Substrates or layers with patterned regions may provide light trapping within the non-scattering portion of the substrate while also providing light trapping within the Si.

In various embodiments, the scattering layer may be formed by lamination, laminated fusion, thin film deposition, or light-induced crystallization (e.g., Fota-Lite™). In one embodiment, a scattering layer or film may be formed by embedding high (or low) index microparticles or microspheres in a thin layer that is planarized. In one embodiment, the bulk or thin layer volumetric scattering material is a phase separated glass or glass ceramic.

A wide variety of materials are suitable for use as volumetric scattering substrates and/or layers. Suitable materials include glass ceramics including but not limited to mullite, beta-quartz, wilemite, canasite, and Dicorm, for example; phase-separated glass (e.g., opals) including but not limited to barium opals, barium silicate opals, fluoride opals, and lead silicate opals, for example; photosensitive glass, including but not limited to Fotalite™ and FotaForm™ (available from Corning Incorporated) for example; and photorefractive materials (including glass, glass ceramics, and crystals).

In each of these materials, scattering particles may be formed in situ from a homogeneous material or added to produce a composite mixture. The materials can be melted by using appropriate processing techniques, including thermal processing techniques (heating, for example), chemical processing techniques (ion-exchange, for example) and/or photosensitive techniques (UV, ultra-violet, and/or laser exposure, for example). In some embodiments, volumetric scattering structures are formed by photolithographic techniques, physically orienting the material (such as by mechanical means such as stretching, or by thermal means such as by applying a thermal gradient across the substrate), or by ion-exchange of the surface layer, for example. In one embodiment, processing techniques cause phase-separation of the substrate material. In one embodiment, processing techniques cause precipitants in the substrate. In one embodiment, processing techniques result in a two-phase media.

In photosensitive glass, for example, FotaLite™ the depth and pattern of the volumetric scattering region or regions can be controlled by controlling the time, area, and intensity of the exposure.

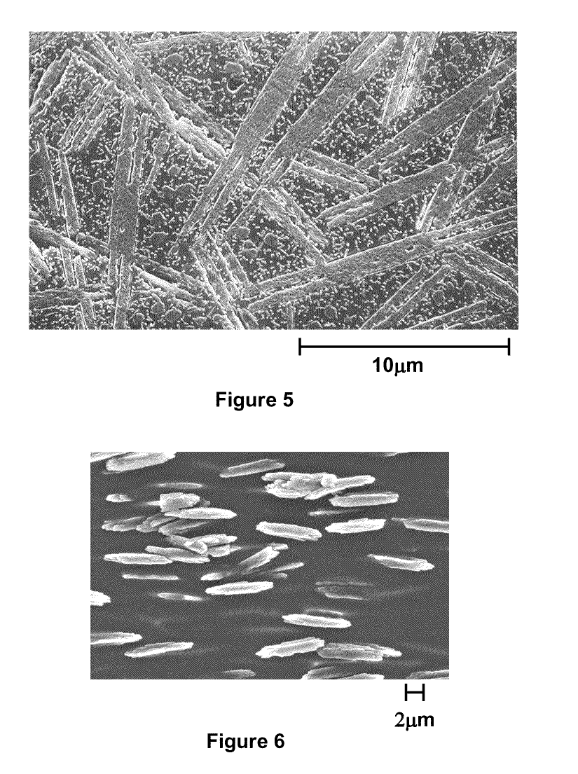

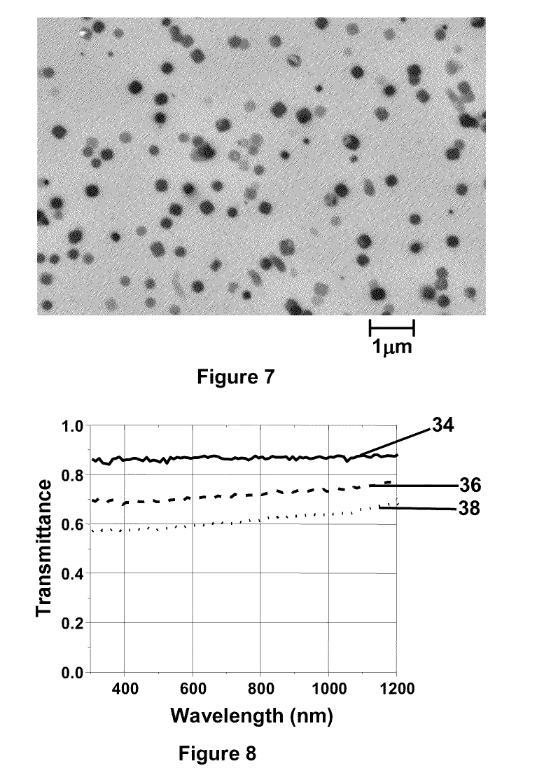

Depending upon the desired properties of the substrate (scattering angles, transmission rates, and wavelength dependence, for example), a wide variety of materials may be used. In PV applications, desirable properties typically include wide angle scattering, high transmission rates, and wavelength independence. Each of those properties can be affected by the scattering particle size, shape, and distribution. Exemplary particle shapes and sizes are illustrated in FIG. 5, FIG. 6, and FIG. 7 which show materials, macor, mullite, and Fota-Lite™ respectively. These materials can be used as the substrate or can be used as the layer or can be used in or for both the substrate and the layer.

In one embodiment, volumetric scattering within the substrate is combined with scattering from a rough surface (such as from a roughened TCO) for overall optimum performance without creating a surface that is so rough as to degrade the PV cell performance. In one embodiment, a rough TCO is provided to reduce the Fresnel reflections expected from planar materials with different indices of refraction (TCO˜2.0, Si˜4).

In the thin (<−100 microns), bulk Si case, with the TCO replaced by EVA and the Si much, much thicker. As in the case of the thin-film Si, there is a trade-off between transmittance and scattering required for light trapping. High transmittance in the visible wavelengths is likely even more critical in this case as the light trapping requirement at these thicknesses is only for the longest wavelengths at which Si absorbs.

According to one embodiment, the substrate is planar. The layer, in one embodiment, is planar. According to another embodiment, the combination of the substrate and layer are planar. One advantage of a volumetric scattering, planar substrate for light scattering is that it overcomes the electrical and crystal growth deficiencies of a structured substrate. Improved quality of the silicon translates directly into improved solar cell performance. For thin film technologies requiring a transparent conductive electrode, the TCO does not need to present a bimodal texture and can therefore be cost effectively deposited using online and continuous CVD system. In addition, the active Si thin films thicknesses can be potentially fine tuned and reduced to minimize module deposition cost.

For thin film technologies which do not require a transparent conductive electrode, the light confinement system is directly integrated within the glass substrate, thereby minimizing the number of module manufacturing steps and results in a durable and cost effective solution. For thin, bulk Si solar cells, a planar scattering substrate offers the advantage of providing light trapping without texture on the top of the superstrate which is exposed to the environment and prone to accumulating dirt. Depending on the process chosen to fabricate the scattering substrate, embodiments also offer the advantage of requiring no subsequent processing steps after substrate formation (e.g., a fusion formable opal glass substrate, in one embodiment). The fabrication processes described below are compatible with very large scale fusion formable substrates such as those currently manufactured by Corning Incorporated for display applications.

Volumetric scattering substrates are capable of producing highly diffuse light distributions. For thin film photovoltaic (PV) applications, embodiments of the volumetric scattering substrates also provide sufficient transmission to allow absorption of the incident light. This implies that there may be an optimum amount of scattering for the competing requirements of light transmission and light trapping.

To evaluate the performance of a substrate with distributed volumetric scattering, a simplified cell architecture was modeled consisting of only the substrate and 1 μm of Si on the substrate. In addition, the backside of the Si was modeled as having a 100% reflecting back surface in the region that the back contact would be in practice. The glass substrate thickness was taken to be 0.7 mm. This model neglected the influence of the TCO. Scattering particles were defined with diameters varying from 50 nm to 2000 nm and having a refractive index of 2.1 or 1.8 in a glass of refractive index 1.51. For each particle size, the density was varied to maximize the maximum achievable current density (MACD). The MACD is defined by the following Formula I:

$$MACD = \frac{q}{hc} \int A ( λ ) {I}_{AM 1.5 G} ( λ ) λ d λ \qquad I$$

wherein q is the elementary charge, h is Planck's constant, c is the speed of light in vacuum, A is the absorptance in the Si as a function of wavelength, I_{AM1.5G} is the solar spectrum and λ is the wavelength. The integral is performed from 300 nm to 1200 nm. The use of MACD assumes that every photon absorbed by the Si is converted into an electron. This is obviously an ideal case that neglects the electrical properties of the material and device. However, it does characterize the light gathering effectiveness of the device structure. The model was built in LightTools by Optical Research Associates with subsequent calculations of Si absorptance and MACD done outside of LightTools.

For particles having n=2.1, wherein n is the refractive index of the particles, the optimized values are shown in Table 1. Particle sizes are diameters of the particles.

TABLE 1

| Particle | Particle | | |
|---|---|---|---|
| Diameter | Density | MACD | % |
| (nm) | (1/mm³) | (mA/cm²) | Improvement |
| None | 0 | 12.5 | |
| 50 | 7.E+10 | 14.2 | 14 |
| 200 | 7.E+07 | 15.8 | 26 |
| 500 | 5.E+06 | 16.4 | 31 |
| 2000 | 6.E+05 | 15.9 | 27 |

For particles having n=1.8, similar percent improvements were found.

The small variation in MACD between 200 nm, 500 nm, and 2000 nm particles may be within the error of the simulation. The refractive index of the particles does not have a significant impact on the results but does change the optimum particle density. The percent improvement over a substrate containing no scattering is also shown in the tables. These are preliminary results and indicate that significant improvement compared to a flat non-scattering substrate is possible.

FIG. 8 provides an example of optimizing the particle density for the best PV cell performance (as determined by MACD) using the 500 nm particle size of n=2.1 particles in a material having n=1.51, where n is the refractive index. The particle density was varied between 1e6 and 1e7 1/mm³. The optimum particle density for a 1 μm layer of crystalline silicon was found to be 5e6 1/mm³. The integrand for calculating the MACD is plotted for three different particle densities. The plot shows a low value especially at longer wavelengths for low particle density, a high value for all wavelength for the optimum particle density, and a low value at short wavelengths and a high value at long wavelengths for a high particle density. Line 34 shows transmission versus wavelength for a particle density (1/mm³) of 1e6. Line 36 shows transmission versus wavelength for a particle density (1/mm³) of 5e6. Line 38 shows transmission versus wavelength for a particle density (1/mm³) of 1e7.

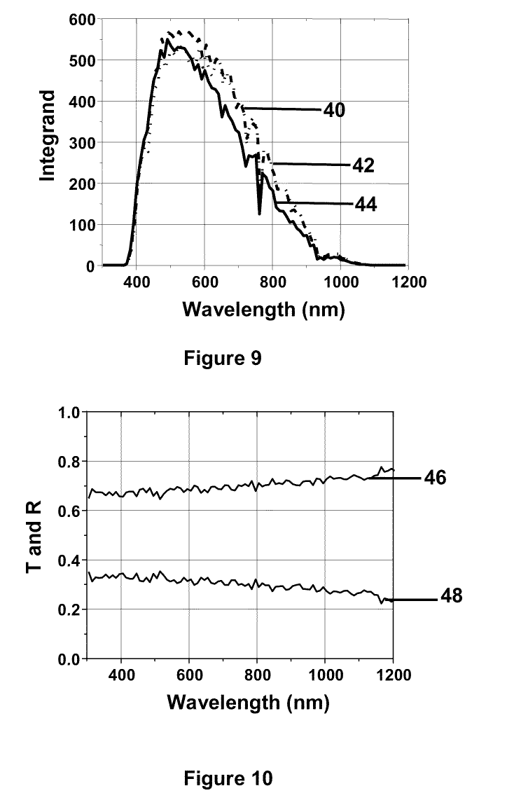

The glass associated with these particle densities was modeled as a slab in air to evaluate the transmittance, reflectance, and scattering properties. The total transmittance as a function of particle density is illustrated in the graph in FIG. 9. As the particle density increases, the total transmittance through the slab decreases as expected. This produces the shift in wavelength dependent properties in the integrand described above. Reduced transmittance at the longer wavelengths enhances the Si absorptance at long wavelengths by redirecting light reflected from the glass/Si interface back toward the Si. This benefit is offset by a decrease in short wavelength transmittance and hence absorptance resulting in an optimum point that balances these two effects. Line 44 shows integrand versus wavelength for a particle density (1/mm³) of 1e6. Line 40 shows integrand versus wavelength for a particle density (1/mm³) of 5e6. Line 42 shows integrand versus wavelength for a particle density (1/mm³) of 1e7.

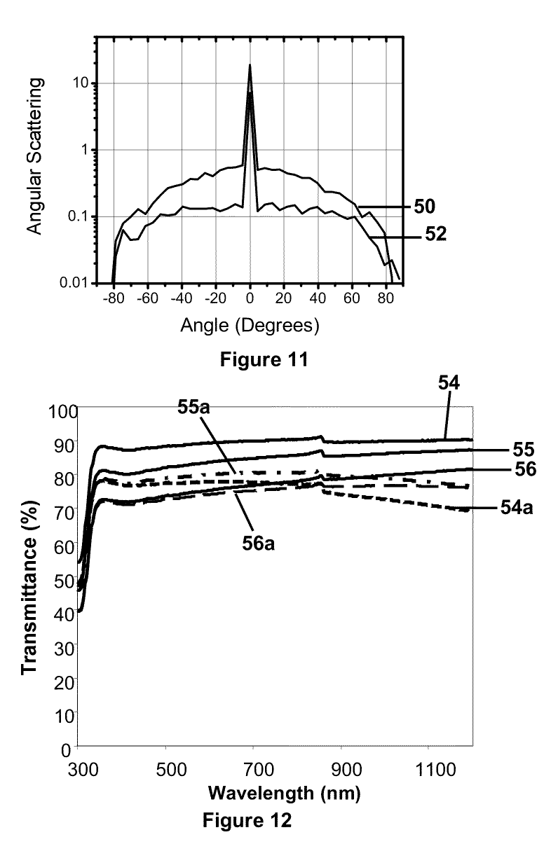

For the optimized particle density of 5e6, the transmittance and reflectance are shown in the graph in FIG. 10 where line 46 is transmittance and line 48 is reflectance. The corresponding angular intensity plot is shown in the graph in FIG. 11 for the optimized particle density which shows a strong specular peak with a broad pedestal of angular scattering. Line 50 is transmitted scattering and line 52 is reflected scattering.

FIG. 12 is a graph of transmittance versus wavelength for substrates, according to one embodiment, using a photosensitive glass. The photosensitive glass, in this example, is Fota-Lite™ which is 2 mm in thickness and exposed to 248 nm with 10 mjoules/pulse. Line 54 shows total transmittance of the glass exposed to 10 pulses. Line 54a shows diffuse transmittance of the glass exposed to 10 pulses. Line 55 shows total transmittance of the glass exposed to 12 pulses. Line 55a shows diffuse transmittance of the glass exposed to 12 pulses. Line 56 shows total transmittance of the glass exposed to 15 pulses. Line 56a shows diffuse transmittance of the glass exposed to 15 pulses.

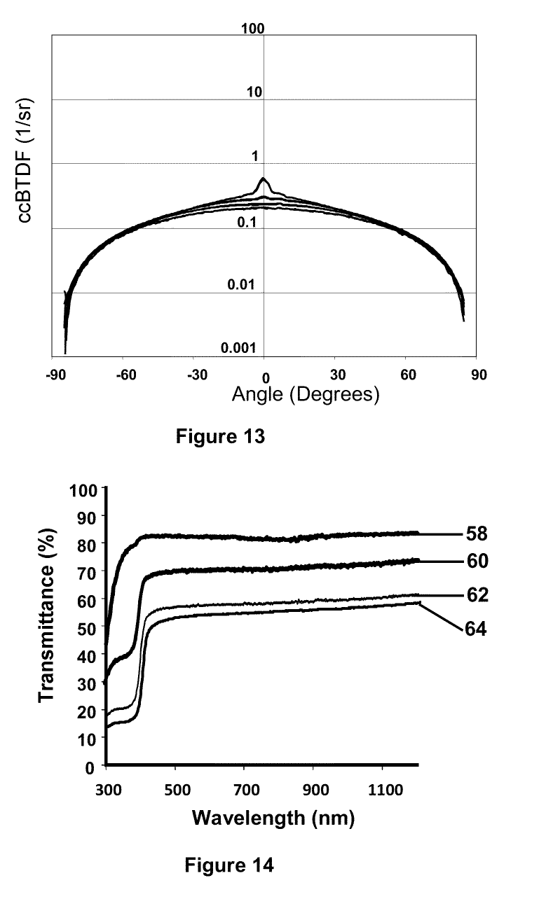

FIG. 13 is a graph of angular intensity, cosine-corrected bidirectional transmission function (ccBTDF) versus angle, for the Fota-Lite™ exposed to 12 pulses for 400 nm, 600 nm, 800 nm, and 1000 nm wavelengths. The graph in FIG. 13 shows a little or no specular peak with a broad angular scattering.

FIG. 14 is a graph of total transmittance versus wavelength for a layer comprising a composite glass matrix containing TiO₂ particles, according to one embodiment. Samples were made wherein the layers comprised 1 percent, 2.5 percent, 5 percent, and 7.5 percent TiO₂. Total transmittance for the layers comprising 1 percent, 2.5 percent, 5 percent, and 7.5 percent TiO₂ is shown by line 58, line 60, line 62, and line 64, respectively.

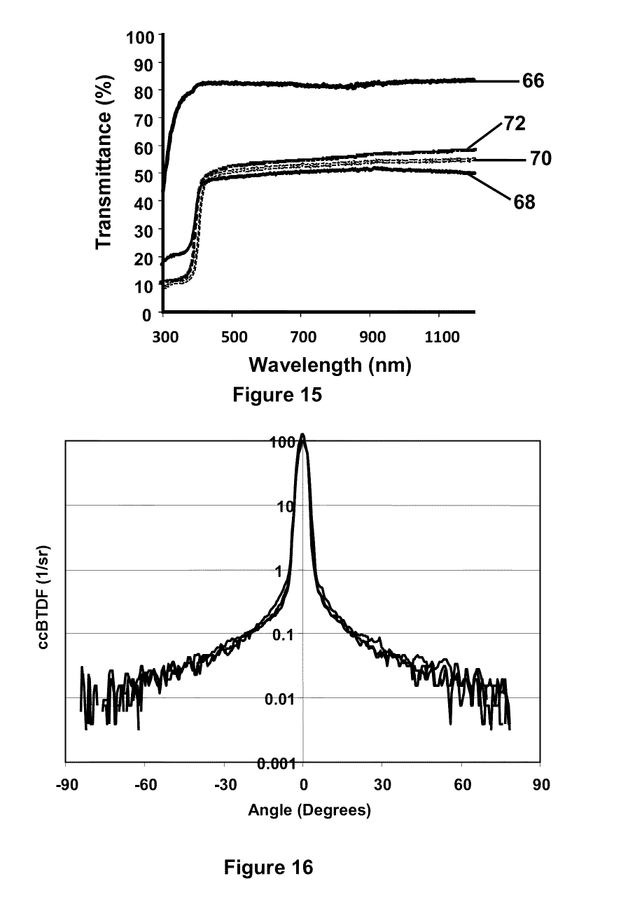

FIG. 15 is a graph of diffuse transmittance versus wavelength for a layer comprising a composite glass matrix containing TiO₂ particles, according to one embodiment. Samples were made wherein the layers comprised 1 percent, 2.5 percent, 5 percent, and 7.5 percent TiO₂. Diffuse transmittance for the layers comprising 1 percent, 2.5 percent, 5 percent, and 7.5 percent TiO₂ is shown by line 66, line 68, line 70, and line 72, respectively.

FIG. 16 is a graph of angular intensity, cosine-corrected bidirectional transmission function (ccBTDF) versus angle, for the layer comprising 1 percent TiO₂ for 450 nm, 600 nm, and 800 nm wavelengths.

Haze can be determined by calculating the ratio of diffuse transmittance to total transmittance.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A photovoltaic device comprising:
a substrate comprising an inorganic matrix and a region having light scattering properties disposed in the inorganic matrix;
a conductive material adjacent to the substrate; and
an active photovoltaic medium adjacent to the conductive material.

2. The device according to claim 1, wherein the conductive material is a transparent conductive film.

3. The device according to claim 2, wherein the transparent conductive film comprises a textured surface.

4. The device according to claim 3, wherein the active photovoltaic medium is in physical contact with the transparent conductive film.

5. The device according to claim 1, further comprising a counter electrode in physical contact with the active photovoltaic medium and located on an opposite surface of the active photovoltaic medium as the conductive material.

6. The device according to claim 1, further comprising a layer comprising an inorganic matrix and a region having light scattering properties disposed in the inorganic matrix, wherein the layer is in physical contact with the substrate and is located between the substrate and the conductive material.

7. The device according to claim 1, wherein the substrate comprises a plurality of regions dispersed throughout the volume of the inorganic matrix.

8. The device according to claim 1, wherein the substrate comprises a plurality of regions dispersed throughout a portion of the volume of the inorganic matrix.

9. The device according to claim 1, wherein the matrix comprises a material selected from glass, glass ceramic, and combinations thereof.

10. The device according to claim 1, wherein the region comprises one or more particles, bodies, spheres, precipitates, crystals, dendrites, phase separated elements, phase separated compounds, air bubbles, air lines, voids or combinations thereof.

11. The device according to claim 10, wherein the region comprises a material selected from a glass, glass ceramic, ceramic, a metal oxide, a metals oxide, and combinations thereof.

12. The device according to claim 1, wherein the active photovoltaic medium comprises multiple layers.

13. The device according to claim 1, wherein the substrate is planar.

14. A photovoltaic device comprising:
a substrate;
a layer comprising an inorganic matrix and a region having light scattering properties disposed in the inorganic matrix;
a conductive material;
wherein the layer is in physical contact with the substrate and is located between the substrate and the conductive material; and
an active photovoltaic medium adjacent to the conductive material.

15. The device according to claim 14, wherein the conductive material is a transparent conductive film.

16. The device according to claim 15, wherein the transparent conductive film comprises a textured surface.

17. The device according to claim 16, wherein the active photovoltaic medium is in physical contact with the transparent conductive film.

18. The device according to claim 14, further comprising a counter electrode in physical contact with the active photovoltaic medium and located on an opposite surface of the active photovoltaic medium as the conductive material.

19. The device according to claim 14, wherein the layer comprises a plurality of regions dispersed throughout the volume of the inorganic matrix.

20. The device according to claim 14, wherein the layer comprises a plurality of regions dispersed throughout a portion of the volume of the inorganic matrix.

21. The device according to claim 14, wherein the matrix comprises a material selected from glass, glass ceramic, and combinations thereof.

22. The device according to claim 14, wherein the region comprises particles, bodies, spheres, precipitates, crystals, dendrites, phase separated elements, phase separated compounds, air bubbles, air lines, voids or combinations thereof.

23. The device according to claim 22, wherein the region comprises a material selected from a glass, glass ceramic, ceramic, a metal oxide, a metals oxide, and combinations thereof.

24. The device according to claim 14, wherein the active photovoltaic medium comprises multiple layers.

25. The device according to claim 14, wherein the layer is planar.

26. The device according to claim 14, wherein the combination of the substrate and layer are planar.
